(19) United States
(12) Patent Application Publication
(10) Pub. No.: US 2012/0037983 A1
(43) Pub. Date: Feb. 16, 2012

(54) Trench mosfet with integrated schottky rectifier in same cell

(75) Inventor: Fwu-Iuan Hshieh, Santa Clara, CA (US)

(73) Assignee: FORCE MOS TECHNOLOGY CO., LTD., Banciao City (TW)

(21) Appl. No.: 12/805,611

(22) Filed: Aug. 10, 2010

(51) Int. Cl. H01L 29/78; H01L 21/336

(52) U.S. Cl. 257/334; 438/270; 257/E29.262; 257/E21.41

(57) ABSTRACT

A semiconductor power device comprising a plurality of trench MOSFETs integrated with Schottky rectifier in same cell is disclosed. The invented semiconductor power device comprises a tilt-angle implanted drift region having higher doping concentration than epitaxial layer to reduce Vf in Schottky rectifier portion and to reduce Rds in trench MOSFET portion while maintaining a higher breakdown voltage by implementation of thick gate oxide in trench bottom of trenched gates. Furthermore, the invented semiconductor power device further comprises a Schottky barrier height enhancement region to enhance the barrier layer covered in trench bottom of trenched source-body-Schottky contact in Schottky rectifier portion.

### FIELD OF THE INVENTION

This invention relates generally to the device configuration and manufacturing methods for fabricating the semiconductor power devices. More particularly, this invention relates to an improved and novel device configuration and manufacturing process for providing trench MOSFET integrated with Schottky rectifier in same cell to improve performance of both MOSFET and Schottky rectifier without degrading breakdown voltage.

### BACKGROUND OF THE INVENTION

In order to achieve higher switching speed and efficiency for semiconductor power device, a Schottky rectifier is normally added in parallel to the semiconductor power device with a parasitic PN body diode to function as a clamping diode to prevent the body diode of the semiconductor power device from turning on. The Schottky rectifier is single carrier, i.e., electron carrier only and that can be drawn simply by the drain electrode. The requirement for the clamping effect is that the forward voltage Vf of the Schottky rectifier is less than the parasitic PN body diode (˜0.7V). As the semiconductor power devices become more miniaturized, there is requirement to integrate the Schottky rectifier as part of the semiconductor power device to reduce the space occupied by the Schottky rectifier. Especially for semiconductor power device with different gate structures, there are growing demands to provide effective solutions to integrate the semiconductor power device and Schottky rectifier in same cell.

FIG. 1 shows a semiconductor power device comprising shielded gate trench (SGT) MOSFET integrated with Schottky rectifier disclosed in U.S. Pat. No. 2009/0072301 where an N-channel trench MOSFET is formed in an N epitaxial layer supported on an N+ substrate. Between every two adjacent trenched gates having shielded gate, a trenched source-body-Schottky contact is opened through an n+ source region into a P body region for electrically connecting the n+ source region and the P body region to a source metal. The trenched source-body-Schottky contact further extends through the P body region covered with a low barrier height metal layer to function as an integrated Schottky rectifier in each cell of the semiconductor power device.

The constrains of the above patented invention is that, a parasitic resistance R_{SGT} (as shown in FIG. 1) always exists in mesa area between two adjacent said trenched gates having shielded gate, when area of the mesa is reduced as result of device shrinking, the parasitic resistance R_{SGT} will be accordingly increased, resulting in higher forward voltage Vf in the Schottky rectifier portion and higher resistance Rds (resistance between drain and source, similarly hereinafter) in SGT MOSFET portion. If only reducing epitaxial layer resistivity for reducing the parasitic resistance R_{SGT}, the breakdown voltage of the semiconductor power device may not be supported due to the lower epitaxial layer resistivity than the conventional devices, which will cause hazardous problem to the semiconductor power device.

Accordingly, it would be desirable to provide a new and improved semiconductor power device configuration and manufacturing method to avoid the constraint discussed above.

### SUMMARY OF THE INVENTION

It is therefore an aspect of the present invention to provide a new and improved semiconductor power device such as a trench MOSFET integrated with a Schottky rectifier in same cell by forming a tilt-angle implanted drift region above trench bottom of trenched gates with doping concentration higher than epitaxial layer. Therefore the parasitic resistance R_{SGT} in FIG. 1 can be reduced, thus reducing Vf in Schottky rectifier portion and Rds in trench MOSFET portion.

Another aspect of the present invention is to form thicker gate oxide in lower portion of the trenched gates to maintain the breakdown voltage while reducing Vf in the Schottky rectifier portion and Rds in the trench MOSFET portion.

Another aspect of the present invention is to form a Schottky barrier height enhancement region surrounding integrated Schottky rectifier on sidewall and bottom of trenched source-body-Schottky contact between every two adjacent said trenched gates with lower doping concentration than the epitaxial layer to enhance the barrier height of the Schottky rectifier for reduction of leakage current Ir between drain and source.

Briefly, in a preferred embodiment, this invention discloses a semiconductor power device comprising a plurality of trenched gates surrounded by source regions of a first conductivity type encompassed in body regions of a second conductivity type opposite to said first conductivity type in active area, said semiconductor power device further comprising: a substrate of said first conductivity type; an epitaxial layer of said first conductivity type encompassing said body regions and said source regions supported on said substrate, having a lower doping concentration than said substrate, said trenched gates formed within said epitaxial layer further having a first gate oxide layer in lower portion of said trenched gates and having a second gate oxide layer in upper portion of said trenched gates, wherein said first gate oxide layer is thicker than said second gate oxide layer; a plurality of tilt-angle implanted drift regions of said first conductivity type formed in mesa area between every two adjacent trenched gates encompassed in said epitaxial layer below said body region and having a higher doping concentration than said epitaxial layer; a plurality of trenched source-body-Schottky contacts penetrating through an insulation layer covering top surface of said epitaxial layer, further extending through said source regions and said body regions and into said tilt-angle implanted drift regions in said active area wherein trench bottom and lower portion of said trenched source-body-Schottky contacts below said body regions covered with a Schottky barrier layer such as Ti silicide, Co silicide and Ta silicide to function as an integrated Schottky rectifier; a plurality of ohmic contact doped regions of said second conductivity type surrounding sidewalls of said trenched source-body-Schottky contacts below said source regions and above the integrated Schottky rectifier region, and having a higher doping concentration than said body regions. In an exemplary embodiment, the semiconductor power device further comprises a Schottky barrier height enhancement region of said first conductivity type surrounding sidewall and bottom of each said trenched source-body-Schottky contact below said ohmic contact doped region, said Schottky barrier height enhancement region has a lower doping concentration than said epitaxial layer. In an exemplary embodiment, each of said trenched gates comprises a bottom shielded gate segment padded by said first gate oxide layer on sidewall of a lower portion of said trenched gate and a top gate segment padded by said second gate oxide layer on sidewall at an upper portion of said trenched gate, wherein said bottom shielded gate segment is insulated from said top gate segment by said second gate oxide layer, wherein said bottom shielded gate segment is connected to a source metal and the top gate segment connected to a gate metal. In an exemplary embodiment, each of said trenched gates comprises a single gate segment padded by said first gate oxide layer on sidewall of a lower portion of said trenched gate and said second gate oxide layer on sidewall at an upper portion of said trenched gate, wherein said single gate segment is connected to a gate metal. In an exemplary embodiment, said ohmic contact doped regions are formed within said body regions. In an exemplary embodiment, said ohmic contact doped regions are formed extended below said body regions for avalanche enhancement. In an exemplary embodiment, the semiconductor power device further comprises a source metal covering top surface of said insulation layer and top surface of said trenched source-body-Schottky contacts. In an exemplary embodiment, said insulation layer further comprises a BPSG (Boron Phosphorus Silicon Glass) layer and an NSG (Nondoped Silicon Glass) layer beneath. In an exemplary embodiment, said trenched source-body-Schottky contacts have greater width within said BPSG layer than within other portions. In an exemplary embodiment, said semiconductor power device further comprises a termination area next to said active area, said termination area further having a plurality of trenched gates penetrating through said body regions and said tilt-angle implanted drift regions and into said epitaxial layer, wherein said trenched gates in termination area are same as those in active area.

Furthermore, this invention disclosed a method to manufacture a semiconductor power device comprising the steps of: opening a plurality of gate trenches in an epitaxial layer of a first conductivity type; carrying out angle ion implantation of said first conductivity type dopant above said gate trenches and diffusing it to form tilt-angle implanted drift region in upper portion of said epitaxial layer and between every two adjacent of said gate trenches, wherein the doping concentration of said tilt-angle implanted drift region is higher than that of said epitaxial layer; forming a first gate oxide layer covering inner surface of said gate trenches and top surface of said epitaxial layer; depositing a first doped poly-silicon layer onto said first gate oxide layer and carrying out dry etching of said first doped poly-silicon layer to a pre-determined depth; carrying out wet etching of said first gate oxide layer removing it from top surface of said epitaxial layer and from sidewalls of upper portion of said gate trenches to expose the top surface of said first doped poly-silicon layer; growing a second gate oxide layer which is thinner than said first gate oxide layer onto sidewalls of said upper portion of said gate trenches, covering top surface of said first doped poly-silicon layer and said first gate oxide layer; depositing a second doped poly-silicon layer onto said second gate oxide layer and etching back said second doped poly-silicon layer leaving it within said gate trenches; carrying out ion implantation of a second conductivity type dopant opposite to said first conductivity type and diffusing it to form body region in upper portion of said epitaxial layer surrounding said gate trenches over said tilt-angle implanted drift regions; carrying out ion implantation of said first conductivity type dopant and diffusing it to form source regions in upper portion of said epitaxial layer surrounding said gate trenches over said body region, wherein said source regions have a higher doping concentration than said epitaxial layer; depositing a layer of NSG and a layer of BPSG successively onto entire top surface; providing a trench mask and carrying out dry oxide etching and dry silicon etching successively to open a contact trench between every two adjacent of said gate trenches through said BPSG layer, said NSG layer, said source region and into said body region; carrying out angle ion implantation of said second conductivity type dopant to form ohmic contact doped region surrounding bottom and sidewall of each said contact trench below said source region; performing a step of RTA and carrying out dry silicon etching to make said contact trench further extending into said tilt-angle implanted drift region; carrying out zero degree ion implantation optionally and angle ion implantation of said first conductivity type dopant to form barrier height enhancement region with lower doping concentration than said epitaxial layer surrounding bottom and sidewall of each said contact trench below said ohmic contact doped region followed by a step of RTA; depositing a barrier layer overlying inner surface of said contact trenches and top surface of said BPSG layer followed by performing a step of RTA; depositing metal material onto said barrier layer and etching back said metal material leaving it within said contact trenches; etching back said barrier layer removing it from top surface of said BPSG layer; depositing a front metal layer onto top surface of said BPSG layer and covering said metal material and said barrier layer.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a trench MOSFET integrated with a Schottky rectifier of prior art.

FIG. 2 is a cross-sectional view of a trench MOSFET integrated with a Schottky rectifier according to the present invention.

FIG. 3 is a cross-sectional view of a trench MOSFET integrated with a Schottky rectifier according to the present invention.

FIG. 4 is a cross-sectional view of a trench MOSFET integrated with a Schottky rectifier according to the present invention.

FIG. 5 is a cross-sectional view of a trench MOSFET integrated with a Schottky rectifier according to the present invention.

FIG. 6 is a cross-sectional view of a trench MOSFET integrated with a Schottky rectifier according to the present invention.

FIGS. 7A˜7J are a serial of side cross-sectional views for showing the processing steps for fabricating the trench MOSFET integrated with a Schottky rectifier as shown in FIG. 2.

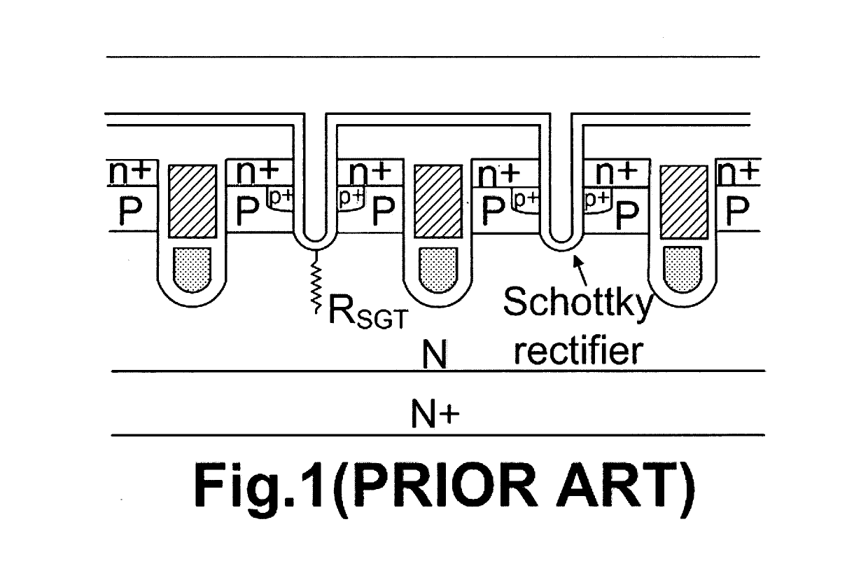

### DETAILED DESCRIPTION OF THE EMBODIMENTS

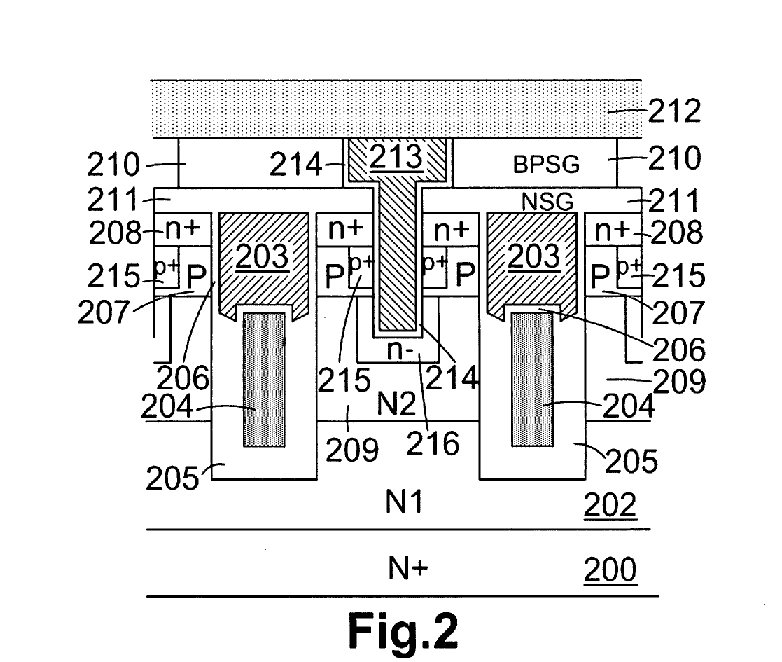

Please refer to FIG. 2 for cross-sectional view of a trench MOSFET integrated with a Schottky rectifier in same cell according to the present invention where an N-channel trench MOSFET is formed on an N+ substrate 200 supporting an N-epitaxial layer 202 with doping concentration N1. A plurality of trenched gates are formed within said N-epitaxial layer 202 and each of these trenched gates includes a top gate segment 203 and a bottom shielded gate segment 204. The bottom shielded gate segment 204 is padded by a thicker gate oxide layer 205 and the top gate segment is padded by a normal gate oxide layer 206 which is thinner than the thicker gate oxide layer 205. Meanwhile, the bottom shielded gate segment 204 is insulated from the top gate segment 203 by portion of the normal gate oxide layer 206 covering top surface of the thicker gate oxide layer 205 and the bottom shielded gate segment 204. A plurality of P-body regions 207 are formed within the N-epitaxial layer 202 and surrounding these trenched gates that include the top gate segment 203 and the bottom shielded gate segment 204. The P-body regions 207 further encompass n+ source regions 208 near top surface of the N-epitaxial layer 202 surrounding these trenched gates. According to the present invention, a plurality of tile-angle implanted drift regions 209 with doping concentration N2 higher than the doping concentration N1 are implemented into a mesa area between every two adjacent trenched gates, above trench bottom of these trenched gates and below said P-body regions 207. The tilt-angle implanted drift regions 209 are formed with a tilt angle implantation process followed by a diffusion process as will be further explained below. The doping concentration N2 may be higher near the trenched gates than at middle of the mesa area between the two adjacent trench gates due to the tilt-angle implantation and diffusion processes. An insulation layer comprising a BPSG layer 210 and an NSG layer 211 beneath is deposited onto top surface of the N-epitaxial layer 202 and these trenched gates. Between every two adjacent of these trenched gates in active area, a trenched source-body-Schottky contact filled with tungsten plug 213 padded by a barrier layer of Ti/TiN or Co/TiN or Ta/TiN 214 is formed penetrating through said insulation layer, said n+ source region 208 and into said P-body region 207 to connect said n+ source region 208 and said P-body region 207 to a source metal 212 such as Ti/Al alloys, Ti/Ni/Ag, Ti/Ni/Au or Ti/Cu. Said trenched source-body-Schottky contact further extends through said P-body region 207 and into said tilt-angle implanted drift region 209 to function as an integrated Schottky rectifier covered with a Schottky barrier layer Ti silicide, Co silicide or Ta silicide. In order to reduce contact resistance between said tungsten plug 213 and said P-body regions 207, a p+ ohmic contact doped region 215 is formed below said n+ source regions 208 within said P-body region 207 surrounding sidewall of said trenched source-body-Schottky contact. Furthermore, in order to enhance barrier height for the Schottky rectifier, an n− Schottky barrier height enhancement region 216 is formed surrounding bottom and sidewall of said trenched source-body-Schottky contact below said p+ ohmic contact doped region 215 with a lighter doping concentration than said N-epitaxial layer 202. By providing the tilt-angle implanted drift regions 209, the Rds in the N-channel trench MOSFSET portion and the Vf in the Schottky rectifier portion are thus reduced while maintain the breakdown voltage with implementation of the thicker gate oxide layer 205 due to reduction of gate-to drain capacitance.

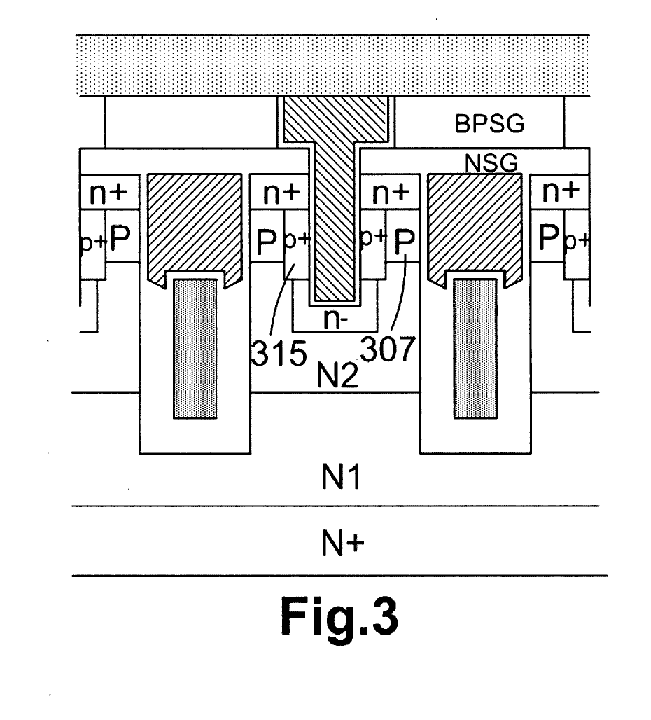

FIG. 3 shows a cross-sectional view of another exemplary embodiment according to the present invention with similar device configuration as the embodiment in FIG. 2. The only difference is that, the p+ ohmic contact doped region 315 in FIG. 3 further extends below the P-body region 307 for avalanche enhancement.

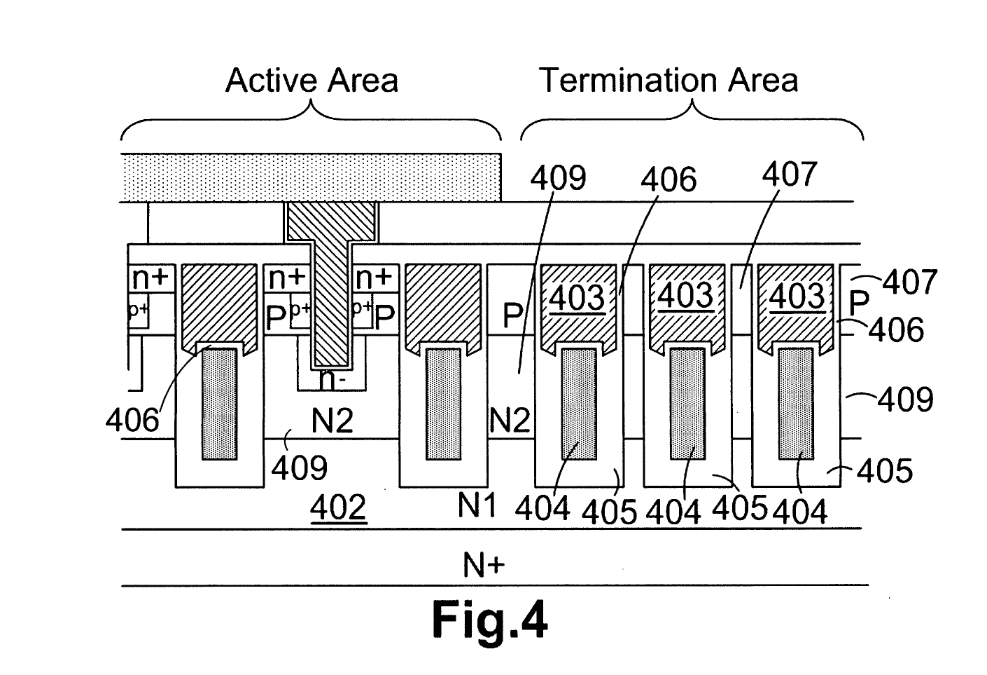

FIG. 4 shows a cross-sectional view of another exemplary embodiment according to the present invention with similar device configuration as the embodiment in FIG. 2. The only difference is that, the exemplary embodiment in FIG. 4 further comprises a termination area next to the active area which is same as FIG. 2. The termination area includes a plurality of trenched gates with each having top gate segment 403 and bottom shielded gate segment 404, the bottom shielded gate segment 404 is padded by a thicker gate oxide layer 405 and the top gate segment 403 is padded by a thinner gate oxide layer 406 which is also insulating the bottom shielded gate segment 404 from the top gate segment 403. A plurality of P-body regions 407 are extending between a pair of these trenched gates and encompassed in N-epitaxial layer 402 having doping concentration N1. Below the P-body regions 407, a plurality of tilt-angle implanted drift regions 409 are formed above trench bottom of these trenched gates with doping concentration N2 higher than the doping concentration N1.

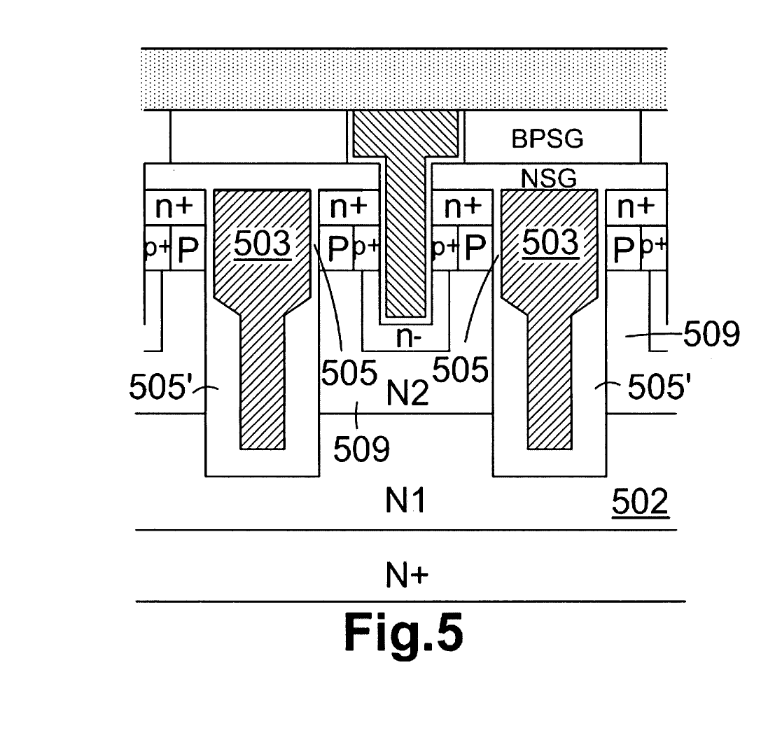

FIG. 5 shows a cross-sectional view of another exemplary embodiment according to the present invention with similar device configuration as the embodiment in FIG. 2. The only difference is that, each of the trenched gates in FIG. 5 only includes single gate segment 503 having greater width in upper portion and having smaller width in lower portion. Furthermore, the upper portion of the single gate segment 503 is padded by a thinner gate oxide layer 505 and the lower portion of the single gate segment 503 is padded by a thicker gate oxide layer 505′ to achieve a lower gate-to-drain capacitance for not degrading breakdown voltage when providing the tilt-angle implanted drift regions 509 with doping concentration N2 higher that of N-epitaxial layer 502 N1.

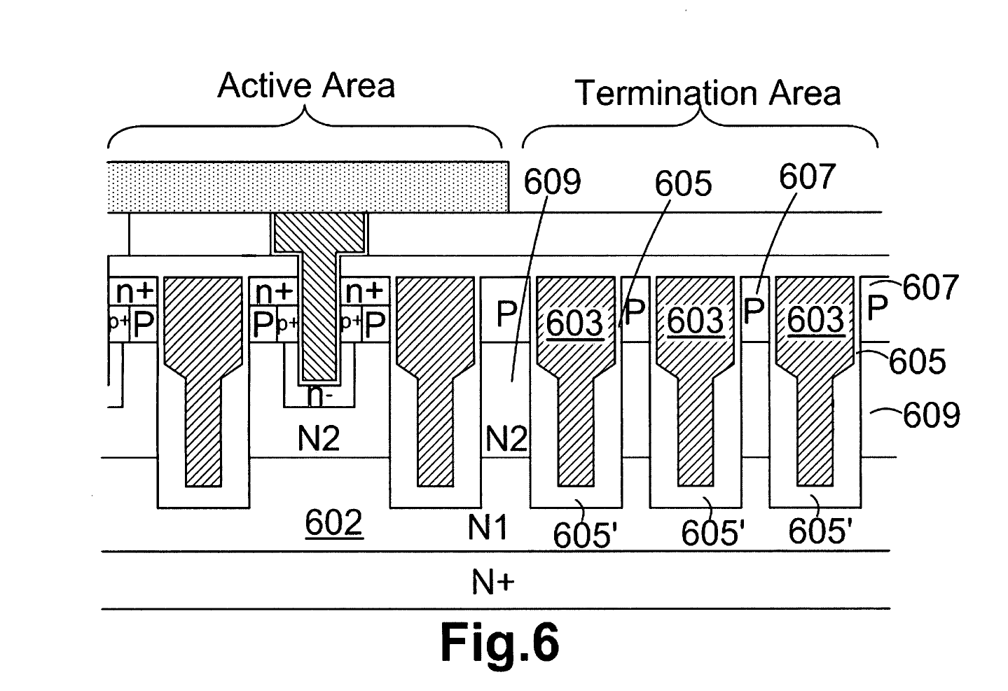

FIG. 6 shows a cross-sectional view of another exemplary embodiment according to the present invention with similar device configuration as the embodiment in FIG. 5. The only difference is that, the exemplary embodiment in FIG. 6 further comprises a termination area next to the active area which is same as FIG. 5. The termination area includes a plurality of trenched gates with each having single gate segment 603 having greater width in upper portion while having smaller width in lower portion. The upper portion of the single gate segment 603 is padded by a thinner gate oxide layer 605 and the lower portion of the single gate segment 603 is padded by a thicker gate oxide layer 605′. A plurality of P-body regions 607 are extending between a pair of these trenched gates and encompassed in N-epitaxial layer 602 having doping concentration N1. Below the P-body regions 607, a plurality of tilt-angle implanted drift regions 609 are formed above trench bottom of these trenched gates with doping concentration N2 higher than the doping concentration N1.

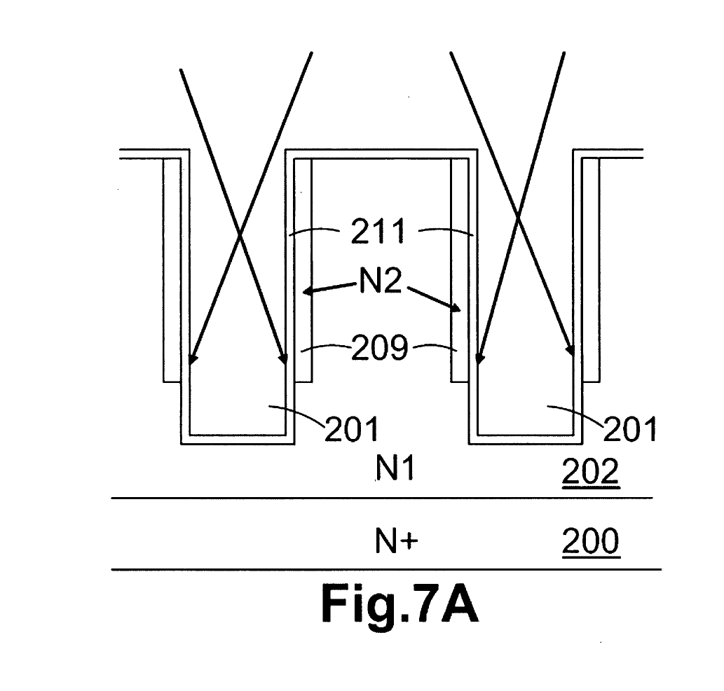

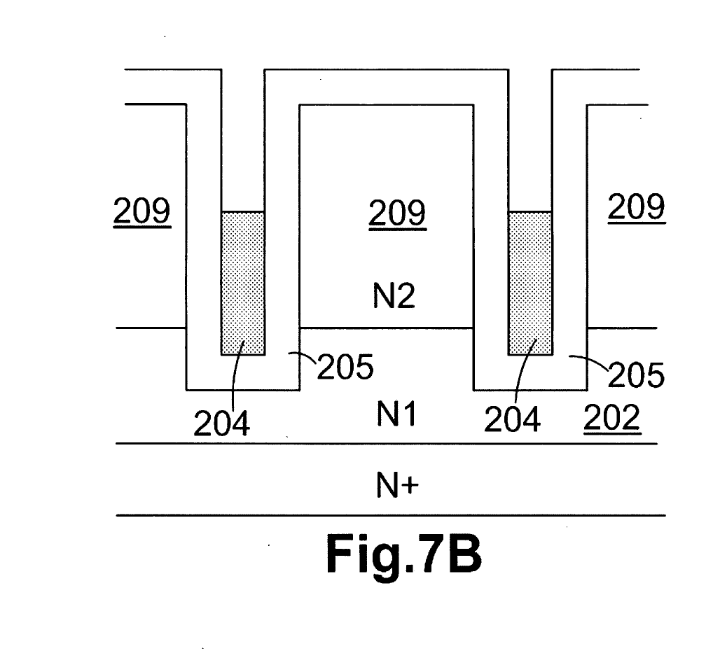

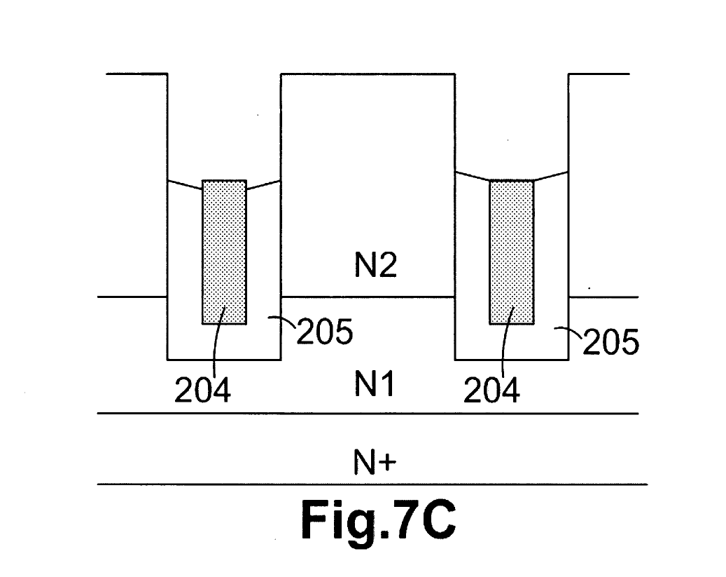

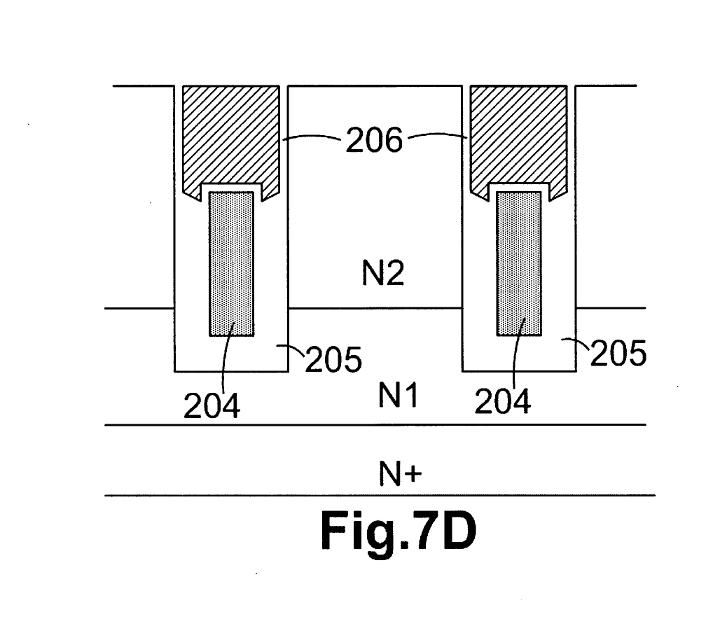

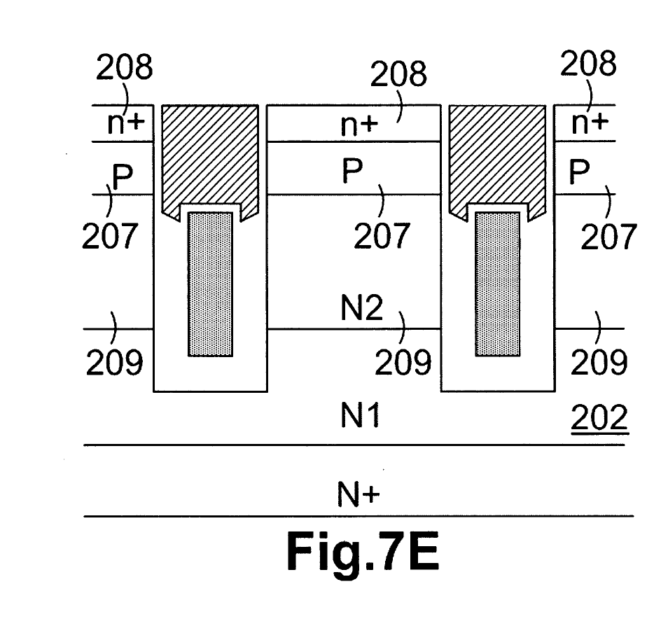

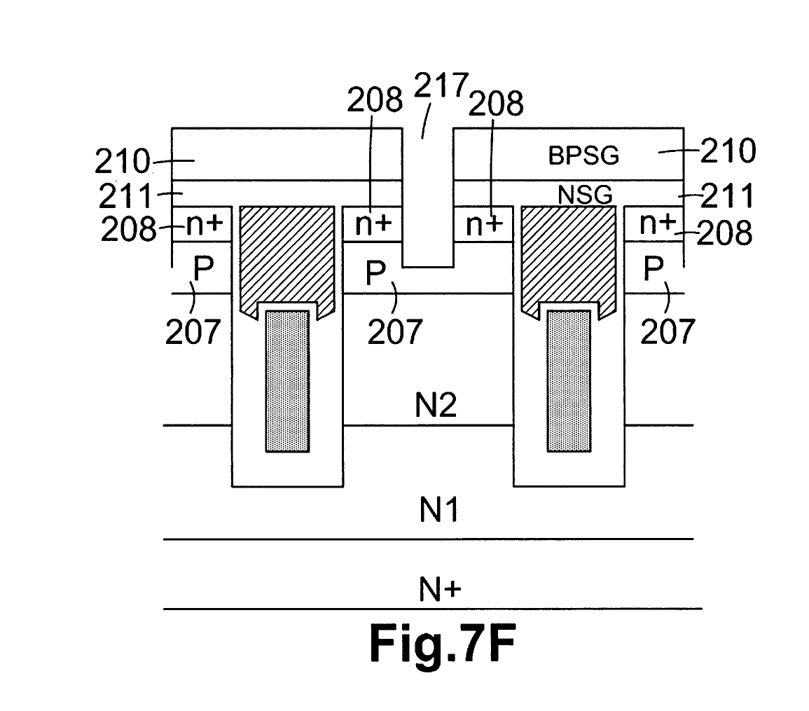

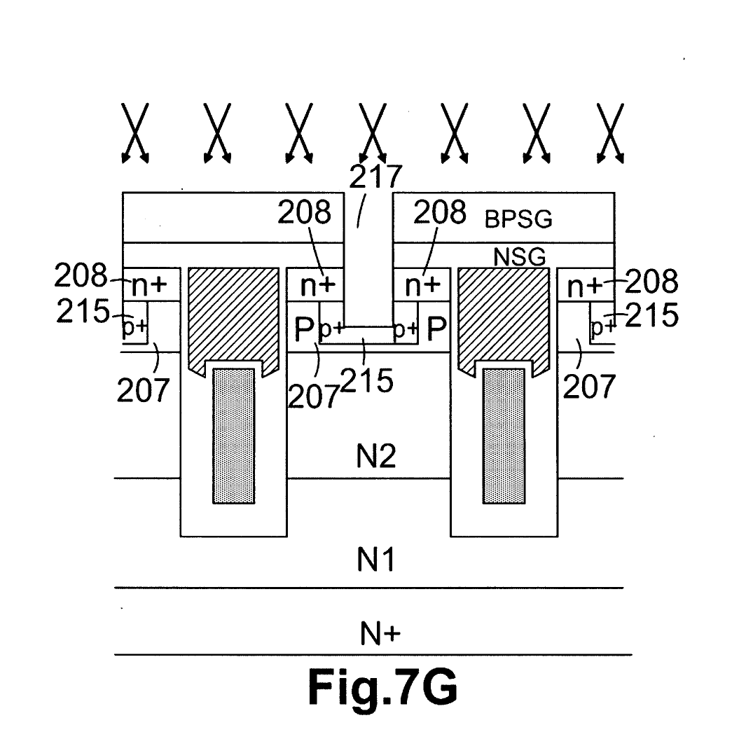

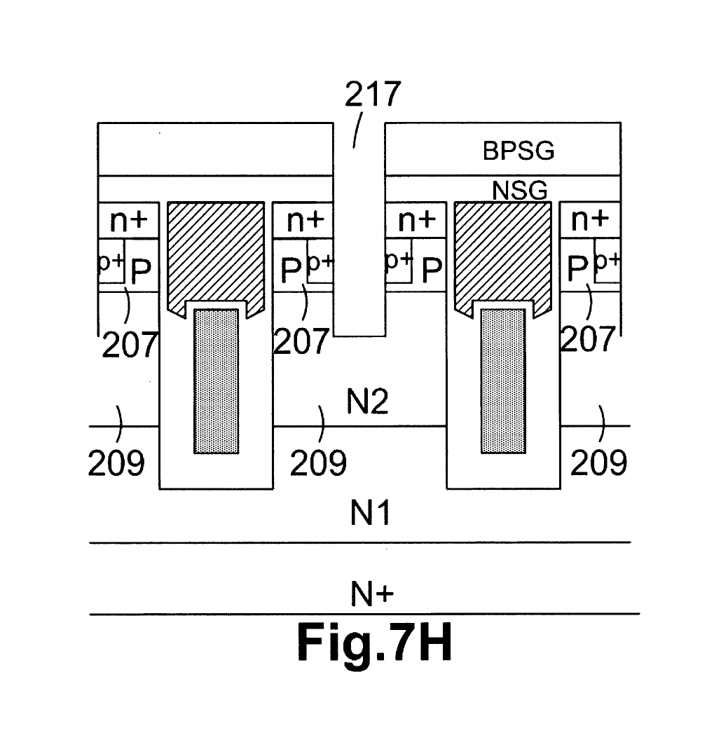

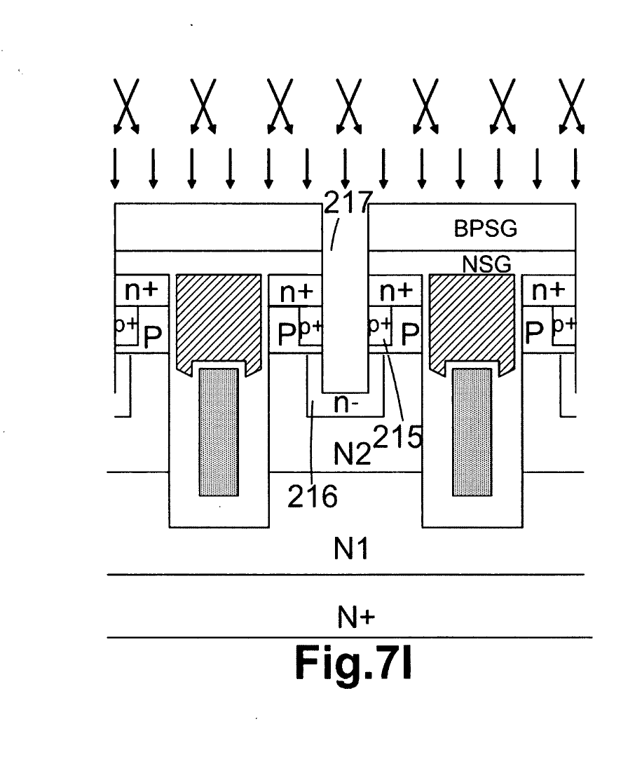

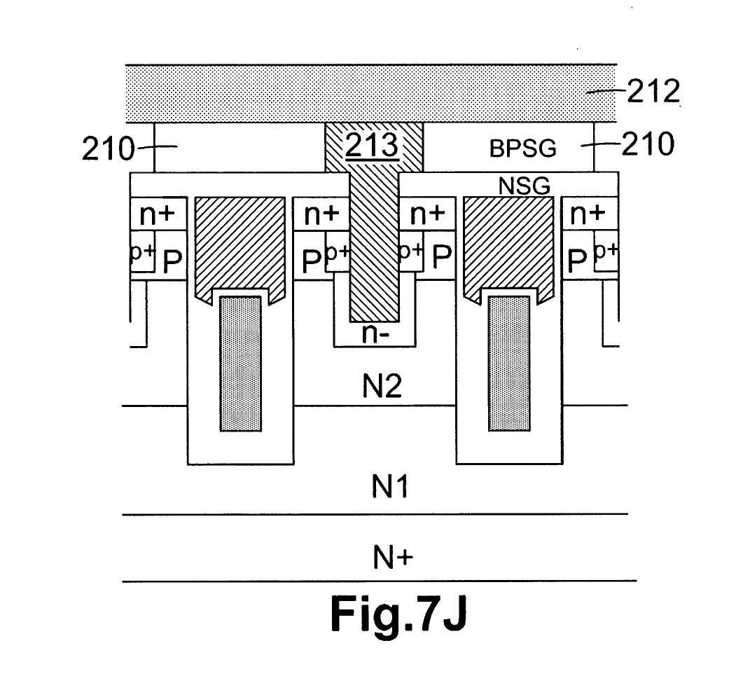

Referring to FIGS. 7A to 7J for a series of cross-sectional views to illustrate the processing steps for manufacturing a trench MOSFET integrated with Schottky rectifier as shown in FIG. 2. In FIG. 7A, a trench mask (not shown) is applied to open a plurality of gate trenches 201 by trench etching process in an N epitaxial layer 202 having doping concentration N1 supported on an N+ substrate 200. Then, a sacrificial oxide layer (not shown) is grown and removed to repair the sidewall surface of the gate trenches 201 damaged by the trench etching process. Next, a screen oxide 211 is grown for preventing an ion implantation damage. Then an Arsenic or Phosphorus angular ion implantation is carried out to form the N tilt-angle implanted drift region 209 having doping concentration N2 higher than the doping concentration N1 around the sidewalls of the gate trenches 201.

In FIG. 7B, an N dopant diffusion is first performed to diffuse the N tilt-angle implanted drift region 209 extending between the gate trenches inside the N-epitaxial layer 202. Then, a first gate oxide layer 205 is deposited or grown overlying inner surface of the gate trenches and top surface of the N-epitaxial layer 202. After that, the gate trenches are filled with a first doped poly-silicon layer 204 followed by dry etching of the first doped poly-silicon layer 204 to remove it from above the top of the gate trenches and further to a pre-determined depth.

In FIG. 7C, a wet etching of the first gate oxide layer 205 is carried out to remove it from the top portions of the gate trenches while keeping it between the first doped poly-silicon layer 204 and sidewall of lower portion of the gate trenches.

In FIG. 7D, a second gate oxide layer 206 is grown to cover top surface of the first gate oxide layer 205, top surface of the first doped poly-silicon layer 204, top surface of the N-epitaxial layer 202 and top portions of the gate trenches sidewalls. Then, the top portion of the gate trenches are filled with a second doped poly-silicon layer 203 followed by CMP (Chemical Mechanical Polishing) or dry etching of the second doped poly-silicon layer 203 to leave it within these gate trenches.

In FIG. 7E, a P type dopant ion implantation is carried out followed by P type dopant diffusion to form P-body regions 207 near top surface of the N-epitaxial layer 202 and above the tilt-angle implanted drift regions 209. Then, an N type dopant ion implantation is carried out followed by N type dopant diffusion to form n+ source regions 208 near top surface of the N-epitaxial layer 202 and above the P-body regions 209.

In FIG. 7F, an NSG layer 211 and a BPSG layer 210 is successively deposited onto top surface of the N-epitaxial layer 202 and the trenched gates followed by applying a contact mask (not shown). Then, a dry oxide etching and a dry silicon etching is successively performed to open a plurality of contact trenches 217 through insulation layer comprising the BPSG layer 210 and the NSG layer 211, through said n+ source regions 208 and further into said P-body regions 207.

In FIG. 7G, a p-type dopant BF2 angle ion implantation is performed to form p+ ohmic contact doped region 215 within said P-body region 207 surrounding bottom and sidewall of each said contact trench 217 below said n+ source regions 208. After that, a step of RTA (Rapid Thermal Annealing) is carried out to activate the P type dopant implanted in the p+ ohmic doped region 215.

In FIG. 7H, the contact trench 217 is further etched by dry silicon etching through said P-body region 207 and further into the tilt-angle implanted drift region 209. In FIG. 7I, a P-type dopant BF2 ion implantation of zero degree is optionally performed followed by an n-type dopant angle BF2 ion implantation to form n− Schottky barrier height enhancement region 216 surrounding bottom and sidewall of each said contact trench 217 below said p+ ohmic doped region 215. After that, a step of RTA (Rapid Thermal Annealing) is carried out to activate the P type dopant implanted in the n− Schottky barrier height enhancement region 216.

In FIG. 7J, a wet etching of the BPSG layer 210 is first performed to enlarge the trench width of the contact trench for better contact performance without significantly enlarging contact CD (Critical Dimension) in the NSG layer 211. Then, a Ti/TiN layer functioning as barrier layer is deposited overlying inner surface of the contact trench and top surface of the BPSG layer followed by a step of RTA to form Ti Silicide as Schottky barrier layer. Onto said barrier layer Ti/TiN, a tungsten material is deposited filling in the contact trench followed by the tungsten etching back to form tungsten plug 213 of trenched source-body-Schottky contact. Next, the barrier layer Ti/TiN is etched back to remove it from top surface of the BPSG layer 210. Then, a front metal layer of Ti/Al alloys or Ti/Ni/Ag is deposited onto top surface of the BPSG layer 210 and the trenched source-body-Schottky contact to function as source metal 212 connected to the n+ source region 208 and the P-body region 207 via tungsten plug 213.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A semiconductor power device comprising a plurality of trenched gates surrounded by source regions of a first conductivity type encompassed in body regions of a second conductivity type opposite to said first conductivity type in active area, said semiconductor power device further comprising:
a substrate of said first conductivity type;
an epitaxial layer of said first conductivity type encompassing said body regions and said source regions supported on said substrate, having a lower doping concentration than said substrate;
said trenched gates formed within said epitaxial layer further having a first gate oxide layer in lower portion of said trenched gates and having a second gate oxide layer in upper portion of said trenched gates, wherein said first gate oxide layer is thicker than said second gate oxide layer;
a plurality of tilt-angle implanted drift regions of said first conductivity type formed in mesa area between every two adjacent said trenched gates encompassed in said epitaxial layer below said body region and having a higher doping concentration than said epitaxial layer;
a plurality of trenched source-body-Schottky contacts penetrating through an insulation layer covering top surface of said epitaxial layer, further extending through said source regions and said body regions and into said tilt-angle implanted drift regions in said active area wherein trench bottom and lower portion trench sidewalls of said trenched source-body-Schottky contacts below said body regions covered with a Schottky barrier layer to function as an integrated Schottky rectifier;
a plurality of ohmic contact doped regions of said second conductivity type surrounding sidewalls of said trenched source-body-Schottky contacts below said source regions, above said integrated Schottky rectifier, and having a higher doping concentration than said body regions.

2. The semiconductor power device of claim 1 further comprising a Schottky barrier height enhancement region of said first conductivity type surrounding said integrated Schottky rectifier disposed on sidewall and bottom of each said trenched source-body-Schottky contact below said ohmic contact doped region, said Schottky barrier height enhancement region has a lower doping concentration than said epitaxial layer.

3. The semiconductor power device of claim 1, wherein each of said trenched gates comprising a bottom shielded gate segment padded by said first gate oxide layer on sidewall of a lower portion of said trenched gate and a top gate segment padded by said second gate oxide layer on sidewall at an upper portion of said trenched gate, wherein said bottom shielded gate segment is insulated from said top gate segment by said second gate oxide layer.

4. The semiconductor power device of claim 3, wherein said bottom shielded gate segment and said top gate segment further comprising doped poly-silicon layer.

5. The semiconductor power device of claim 3, wherein said bottom shielded gate segment is connected to a source metal and said top gate segment connected to a gate metal.

6. The semiconductor power device of claim 1, wherein each of said trenched gates comprising a single gate segment padded by said first gate oxide layer on sidewall of a lower portion of said trenched gate and said second gate oxide layer on sidewall at an upper portion of said trenched gate.

7. The semiconductor power device of claim 6, wherein said single gate segment further comprising doped poly-silicon layer connected to a gate metal.

8. The semiconductor power device of claim 1, wherein said ohmic contact doped regions are formed within said body regions.

9. The semiconductor power device of claim 1, wherein said ohmic contact doped regions are formed extended below said body regions for avalanche enhancement.

10. The semiconductor power device of claim 1, wherein said semiconductor power device further comprising trenched metal oxide semiconductor field effect transistor.

11. The semiconductor power device of claim 1, wherein said trenched source-body-Schottky contacts are filled with tungsten plugs padded by a barrier layer Ti/TiN, Co/TiN or Ta/TiN.

12. The semiconductor power device of claim 11 further comprising a source metal covering top surface of said insulation layer and said tungsten plugs filled in said trenched source-body-Schottky contacts.

13. The semiconductor power device of claim 1, wherein said insulation layer further comprising a BPSG layer and an NSG layer beneath.

14. The semiconductor power device of claim 13, wherein said trenched source-body-Schottky contacts have greater width within said BPSG layer than within other portions.

15. The semiconductor power device of claim 1 further comprising a termination area next to said active area, said termination area further having a plurality of trenched gates penetrating through said body regions and said tilt-angle implanted drift regions and into said epitaxial layer, wherein said trenched gates in said termination area are same as those in active area.

16. The semiconductor power device of claim 1, wherein said Schottky barrier layer is Ti silicide, Co silicide or Ta silicide.

17. The semiconductor power device of claim 12, wherein said source metal is Ti/Al alloys, Ti/Ni/Ag or Cu.

18. The semiconductor power device of claim 1, wherein said tilt-angle implanted drift regions have lower doping concentration at middle of said mesa area between every two adjacent said trenched gates than edges of said mesa area near said trenched gates.

19. The semiconductor power device of claim 1, wherein said tilt-angle implanted drift regions are disposed above trench bottom of said trenched gates.

20. A method for manufacturing a semiconductor power device comprising the steps of:
opening a plurality of gate trenches in an epitaxial layer of a first conductivity type;
carrying out angle ion implantation of said first conductivity type dopant above said gate trenches and diffusing it to form tilt-angle implanted drift region in upper portion of said epitaxial layer and between every two adjacent of said gate trenches, wherein the doping concentration of said tilt-angle implanted drift region is higher than that of said epitaxial layer;
forming a first gate oxide layer covering inner surface of said gate trenches and top surface of said epitaxial layer;
depositing a first doped poly-silicon layer onto said first gate oxide layer and carrying out dry etching of said first doped poly-silicon layer to a pre-determined depth;
carrying out wet etching of said first gate oxide layer removing it from top surface of said epitaxial layer and from sidewalls of upper portion of said gate trenches to expose the top surface of said first doped poly-silicon layer;
growing a second gate oxide layer which is thinner than said first gate oxide layer onto sidewalls of said upper portion of said gate trenches, covering top surface of said first doped poly-silicon layer and said first gate oxide layer;
depositing a second doped poly-silicon layer onto said second gate oxide layer and etching back said second doped poly-silicon layer leaving it within said gate trenches;
carrying out ion implantation of a second conductivity type dopant opposite to said first conductivity type and diffusing it to form body region in upper portion of said epitaxial layer surrounding said gate trenches over said tilt-angle implanted drift regions;
carrying out ion implantation of said first conductivity type dopant and diffusing it to form source regions in upper portion of said epitaxial layer surrounding said gate trenches over said body region, wherein said source regions have a higher doping concentration than said epitaxial layer;
depositing a layer of NSG and a layer of BPSG successively onto entire top surface;
providing a trench mask and carrying out dry oxide etching and dry silicon etching successively to open a contact trench between every two adjacent of said gate trenches through said BPSG layer, said NSG layer, said source region and into said body region;
carrying out angle ion implantation of said second conductivity type dopant to form ohmic contact doped region surrounding bottom and sidewall of each said contact trench below said source region;
performing a step of RTA and carrying out dry silicon etching to make said contact trench further extending into said tilt-angle implanted drift region;
carrying out zero degree ion implantation optionally and angle ion implantation of said first conductivity type dopant to form barrier height enhancement region with lower doping concentration than said epitaxial layer surrounding bottom and sidewall of each said contact trench below said ohmic contact doped region followed by a step of RTA;
depositing a barrier layer overlying inner surface of said contact trenches and top surface of said BPSG layer followed by performing a step of RTA;
depositing metal material onto said barrier layer and etching back said metal material leaving it within said contact trenches;
etching back said barrier layer removing it from top surface of said BPSG layer;
depositing a front metal layer onto top surface of said BPSG layer and covering said metal material and said barrier layer.

21. The method of claim 20, wherein said barrier layer is Ti/TiN or Co/TiN or Ta/TiN.

22. The method of claim 20, wherein said metal material is tungsten material.

23. The method of claim 20, wherein said front metal layer is Ti/Al alloys, Ti/Ni/Ag or Cu.

24. The method of claim 20, wherein etching back said second doped poly-silicon layer comprising CMP or dry etching.
